(19) United States
(12) Patent Application Publication
(10) Pub. No.: US 2023/0191356 A1
(43) Pub. Date: Jun. 22, 2023

(54) PLASMA POWER SUPPLY USING AN INTERMITTENT POWER SOURCE

(71) Applicant: Nitricity, Inc., San Francisco, CA (US)

(72) Inventors: William C. King, Pflugerville, TX (US); John A. Schwalbe, Redwood City, CA (US); Joshua M. McEnaney, San Francisco, CA (US); Nicolas H. Pinkowski, San Francisco, CA (US)

(21) Appl. No.: 18/082,797

(22) Filed: Dec. 16, 2022

Related U.S. Application Data
(60) Provisional application No. 63/290,845, filed on Dec. 17, 2021.

(51) Int. Cl. B01J 19/08; B01J 35/00

(52) U.S. Cl. CPC B01J 19/088; B01J 35/0033; B01J 2219/0894

(57) ABSTRACT

Aspects of the present disclosure involve a power supply circuit for powering a plasma reactor and more specifically initiating and maintain a plasma therein, and that can operate with power from an intermittent power source. The power supply may include an auxiliary-power supply or trigger circuit, in addition to a primary-power supply circuit, which can reduce the need for high-voltage equipment in the high-power section of the power supply. In one particular use, the power supply includes a high-voltage power output that may be used for generating a plasma between electrodes, for example, in a nitrogen-fixation plasma system. The power supply circuit may provide the flexibility to power a plasma reactor using an intermittent power source, such as solar, wind, and/or a periodic low-cost power grid, while reducing wasteful power conditioning, lowering the cost of operation, and increasing the efficiency of chemical production from the renewable energy.

### CROSS-REFERENCE TO RELATED APPLICATION

This application is related to and claims priority under 35 U.S.C. § 119(e) from U.S. Patent Application No. 63/290,845 filed Dec. 17, 2021, entitled “PLASMA POWER SUPPLY USING AN INTERMITTENT POWER SOURCE,” the entire contents of which is incorporated herein by reference for all purposes.

### TECHNICAL FIELD

Embodiments of the present invention generally relate to a power supply system for generating a plasma and maintaining a plasma within a plasma chamber. More specifically, the present invention relates to systems and methods for producing a sufficiently high voltage to initiate a plasma where the power for the supply comes from an intermittent and/or renewable source. The plasma is for chemical production and particularly may be for producing nitric acid an associated nitrogen-based fertilizers.

### BACKGROUND AND INTRODUCTION

Solar and wind energy are abundant and increasingly cost-effective sources of electricity. However, storing the energy obtained from the solar and wind sources and coordinating its usage with the load demand of an AC grid remains expensive and complex. In one example, plasma-arc, chemical-production systems represent an opportunity to use cheap, intermittent electricity directly, but efficient plasma-arc systems can also have demanding load characteristics that may require a power supply capable of delivering such conditions sustainably. Commercially available power supplies are typically not capable of receiving an intermittent source of power while responding to a fast-ramping plasma-discharge load. For example, conventional power supplies are typically designed to function with consistent two or three phase alternating current as the input, not intermittent sources of power.

For solar or wind power, which is intermittent but may be particularly advantageous in agricultural settings, a plasma-arc, chemical-production system using a conventional power supply would require a large battery bank and an inverter, adding a large cost to installation and maintenance of the system. Moreover, initiating and then sustaining a plasma is a unique challenge for conventional power supplies as the initiating the plasma generally requires a high voltage, but then rapidly presents a near short circuit condition to the power supply. This short-circuit condition may significantly damage or destroy a power supply that is not adequately protected. Current-limiting resistors or inductors may be included in the power supply to handle such a load presented during the near short circuit condition of the plasma-arc system. However, current-limiting resistors may add a significant parasitic energy consumption to the circuit, reducing the total energy efficiency of the plasma-arc process, presenting a challenge when using a renewable source where energy efficiency is of paramount concern. Also, power supplies configured to handle this rapid shift in load may require expensive high-voltage components in the output stage or transformers.

Additionally, and more generally, many conventional fertilizer production methods, particularly those related to conventional ammonia production techniques, involve a natural gas source. The production of ammonia, as well as nitric acid that is produced from ammonia, generate various greenhouse gas byproducts. As such, there is a need for techniques to produce fertilizers in more sustainable ways, including using alternative energy sources and techniques that may avoid use of natural gas as a feed stock.

It is with these observations in mind, among others, that aspects of the present disclosure were conceived and developed.

### SUMMARY

One aspect of the present disclosure is related to a power supply for a plasma reactor from which nitrogen-based fertilizer may be locally produced from a renewable source such as solar or wind. The power supply may comprise a primary power supply circuit converting an input power signal from a power source to a high-voltage power signal to maintain a plasma-arc, a trigger power supply circuit generating an ignition power pulse signal to ignite the plasma-arc, and a controller in communication with the primary power supply circuit and the trigger power supply circuit, the controller generating one or more control signals to activate, based on a measured performance state of the plasma reactor, the trigger power supply circuit.

Another aspect of the present disclosure is related to a power supply. The power supply may include a primary-power supply circuit receiving a power signal from a power source and outputting a primary-power signal and comprise a bridge circuit in electrical communication with the initial-power signal and controlled by phase-offset-activation signals and a high-voltage inductor device in electrical communication with an output of the bridge circuit. The power supply may also include a transformer electrically connected to an output of the inductor device, the transformer amplifying the primary power signal to the plasma reactor and a trigger-power supply circuit converting the power signal from the power source to a high-voltage, ignition-power-pulse signal added to the primary-power signal to ignite a plasma-arc.

Another aspect of the present disclosure is related to a method for controlling a plasma reactor. The method may include the operations of generating, from a primary power supply circuit, a primary power signal from an initial power signal received from a power source, detecting a high-resistance condition across a plurality of electrodes of the plasma reactor, generating, from a trigger-power-supply circuit different than the primary-power-supply circuit, an ignition-power-pulse signal to ignite the plasma-arc, and controlling the primary-power-supply circuit to generate a sustaining-power signal to sustain the plasma-arc.

Yet another aspect of the present disclosure is related to a for controlling a plasma reactor. The method may include the operations of measuring, from a power source and at a power supply, an indication of available power from an intermittent power source, setting, based on the initial indication of available power, a first power set point for the power supply, and determining a change in the available power from the intermittent power source. The method may also include adjusting, based on the determined change in the available power from the intermittent power source, the power set point for the power supply, wherein adjusting the power set point provides a power signal to the plasma reactor corresponding to the available power from the intermittent power source.

### BRIEF DESCRIPTION OF THE DRAWINGS

The foregoing and other objects, features, and advantages of the present disclosure set forth herein should be apparent from the following description of particular embodiments of those inventive concepts, as illustrated in the accompanying drawings. The drawings depict only typical embodiments of the present disclosure and, therefore, are not to be considered limiting in scope.

FIG. 1 is a block diagram of a plasma-arc power supply for producing a high-voltage alternating-current (AC) output configured for integration with an intermittent power source.

FIG. 2 is a circuit diagram of a plasma-arc power supply for producing a high-voltage AC output utilizing a trigger circuit and configured for integration with an intermittent power source.

FIG. 3 is a block diagram of a plasma-arc power supply using a high-voltage direct-current (DC) power supply utilizing a trigger circuit and configured for integration with an intermittent power source.

FIG. 4 is a flowchart of a method for controlling a plasma-arc power supply utilizing a trigger circuit for integration with an intermittent power source.

FIG. 5 is a flowchart of a method for adjusting a power setpoint of a plasma-arc power supply based on an available input power from a power source.

FIG. 6 is a diagram illustrating an example of a computing system that may be used in implementing embodiments of the present disclosure.

### DETAILED DESCRIPTION

Aspects of the present disclosure involve a power supply circuit that may power a plasma reactor and more specifically may provide power sufficient to initiate the plasma and maintain the plasma therein, and that can operate with power from an intermittent power source. The power supply is useful in various possible plasma-based production system. One possible such system can be deployed relatively locally and on a relatively small scale and produce fertilizer from a renewable source, like solar, and do so using water and air from the atmosphere thereby providing many advantages to an agricultural operation and the environment. In one particular example, the power supply includes an auxiliary-power supply or trigger circuit, in addition to a primary-power supply circuit, which can reduce the need for high-voltage equipment in the high-power section of the power supply. In one particular use, the power supply includes a high-voltage power output that may be used for generating a plasma between electrodes, for example, in a nitrogen-fixation plasma system. The power supply circuit may provide the flexibility to power a plasma reactor using an intermittent power source, such as solar, wind, and/or a periodic low-cost power grid, while reducing wasteful power conditioning, lowering the cost of operation, and increasing the efficiency of chemical production from the renewable energy.

In one implementation, the power supply circuit may include a primary-power supply circuit, a trigger power supply circuit, and a controller. A power source, which may be an intermittent-power source, provides power to the primary-power supply and/or the trigger power supply. The controller may generate one or more control signals to control the operation of the primary-power supply circuit and/or the trigger-power supply circuit. In one instance, the controller may, in response to a measurement of an operational state of a plasma reactor or in response to a measured power signal from the power source, cause the trigger power supply to generate an ignition power signal pulse. The ignition power signal may be provided to the plasma reactor to generate an arc and thereby ignite a plasma in the chamber. Upon detection of the plasma, the controller may further cause the primary power supply to provide a high-voltage power signal to the reactor to maintain the plasma for some time. The control of the trigger power supply and the primary power supply may be coordinated by the controller to ignite the plasma utilizing the trigger power supply and maintain the plasma utilizing the primary power supply.

In some implementations, the controller may execute a plasma-arc-monitoring method to coordinate and otherwise utilize the combination of the primary power supply and trigger power supply for powering the plasma reactor. The method may execute on a continuous loop at a certain frequency to achieve suitable control over the plasma-arc. This frequency may be higher than the typical frequency at which an arc forms and breaks in the plasma reactor. The method may include determining a status of the arc. If the arc is ignited as indicated by a substantial flow of current through the plasma reactor, then the primary power supply may be controlled to continue to power the arc. If the system detects that the arc is extinguished or otherwise off, as indicated by a lack of current flow through the plasma reactor, the trigger power supply may be controlled to initiate an arc.

In general, high-voltage and/or high-current power supplies are expensive utilizing components customized to be able to handle the peak power output, while the operating average output that typically a fraction of the peak power. Through the circuits and methods described herein, each component of the power supply may be operated closer to a designed peak power, saving costs at any given power (high-voltage, low-current trigger power and low-voltage, high-current primary power). Alternatively, a power supply may be controlled to ramp the current up after an initial, low current, high-voltage spark in a single circuit. However, the timescale of reignition in such a design is typically fast enough that controlling the power supply accordingly would be challenging and difficult to adjust. The separation of the primary-power supply and trigger-power supply of the circuits and methods described herein allow for setting and adjusting the voltage and the current of the power supplies independently.

In addition, the controller may receive a measurement (which term measurement includes calculation from measured parameters such as voltage and current) of the power provided by the power source and/or the power provided to the plasma reactor and use the measurement to adjust a power setpoint for the power supply. In general, the power setpoint determined by the controller may correspond to a point at which the power from the power source (which may be an intermittent-power source) is most efficiently transferred to the output power to the plasma reactor. As the power from the power source may vary, the controller may adjust the setpoint accordingly to maintain an efficient transfer of power to the reactor. The power setpoint may be adjusted in relation to the trigger power supply and/or the primary power supply based on one or more measurements of the power supply circuit, including but not limited to the input power from the power source and the output power to the plasma reactor. The process of measuring one or more aspects of the power supply circuit and adjusting the power setpoint may be repeated periodically to response to changes in the power provided by an intermittent power source.

These and other advantages are gained through the devices and methods described herein.

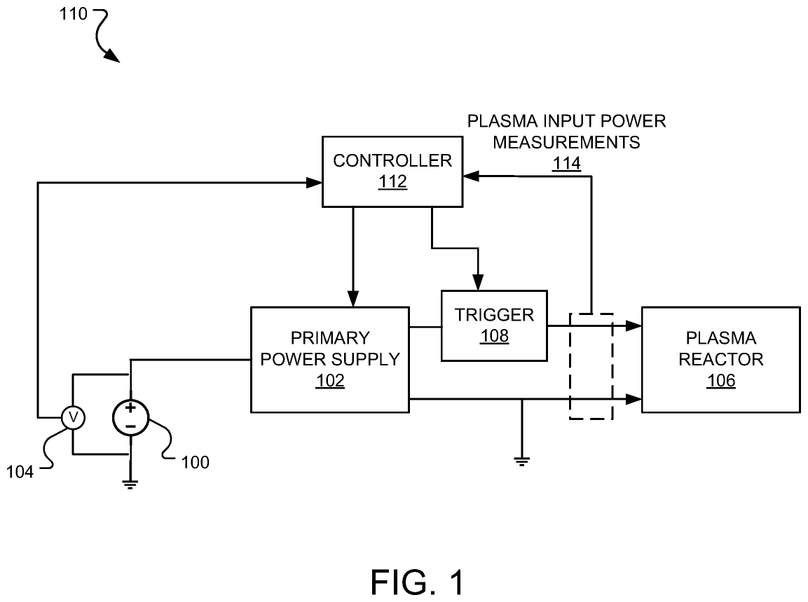

FIG. 1 is a block diagram of a plasma-arc power supply circuit 110 for producing a high-voltage alternating current (AC) output from an intermittent- or low-power source. For example, the power supply circuit 110 may convert a low or intermittent power supply, such as from solar or wind power, into a high-voltage power source for providing power for generating a plasma between electrodes of a plasma generating system. While aspects of the disclosure are particularly useful for connecting to an intermittent power source such as a solar array or wind turbine, the power supply may also be couple to a conventional grid. Moreover, the power supply may also receive power from a combination of intermittent supplies and a grid. In one possible implementation, the generated plasma may be utilized in a nitrogen-fixation plasma system. Conventional power supplies are not capable of addressing intermittent power and managing the fast-ramping plasma discharge loads of such systems. The plasma-arc power supply circuit 110 of FIG. 1 may include an auxiliary power supply and/or a trigger circuit to reduce the need for high-voltage equipment in the high-power portion of the supply and make the power supply effective to power a plasma-arc system with many types of power sources.

The power supply circuit 110 of FIG. 1 may receive power from a power source 100. The power source may be any kind of power source 100 and, in some instances, may include an intermittent source such as a solar power source, a wind power source, or any other type of renewable power source. The intermittent power source may include one or more batteries or other forms of energy storage for use by the power supply circuit 110. While suitable for operation with an intermittent power source, the power source 100 may be connected with a power grid or other mains power source. Regardless of the type of power source 100, power may be provided to a primary power supply 102. In some instances, such as in the case of a solar power source, the voltage of the source power 100 may be measured by voltmeter 104 to determine the power available from the power source. Other measurement devices may be included in circuit 110 to measure or estimate the available power from the power source 100, such as a current meter, potentiometer, or a solar irradiance meter.

The primary power supply 102 may be configured to produce an alternating current (AC) or direct current (DC) power signal from the available power of the power source 100. The power signal produced by the primary power supply 102 may be used to power a plasma reactor 106.

Aspects of the present disclosure may involve a gliding-arc type plasma reactor for use in nitrogen-based fertilizer production. Gliding-arc plasma reactors have a natural tendency to produce electric arcs with a favorable combination of electric field and plasma temperature. By encouraging these conditions, an appropriately-designed reactor can efficiently produce nitrogen compounds for fertilizer. In one implementation, a plasma reactor may include a pair of electrodes oriented in a plane within an enclosure or chamber between which a large voltage difference may be held sufficient to form and maintain a plasma within the chamber. Further, the plasma-arc may be a gliding-arc type plasma reactor such that the plasma-arc glides up the electrodes.

In this or other implementations, the plasma reactor may also include a gas injection system to introduce a gas into the chamber for interacting with the plasma-arc. The gas may be injected into the chamber of the reactor through one or more pipes that may or may not include an adjustable nozzle. The nozzle may direct air flow, including the gas, at a location at which the plasma-arc may occur. For example, the onset of the plasma-arc is most likely to occur between the electrodes such that the nozzle may direct the inflow of gas to a location at or near the area between the electrodes. Directing the inflow of gas to the strike point of the plasma-arc may aid in directing the glide of the arc up the electrodes. As such, the plasma reaction device disclosed herein provides for creation of a non-thermal plasma within the chamber for nitrogen fixation at a high efficiency.

In some implementations of the circuit 110, the primary power supply 102 may be configured to provide 95% or more of the total power to the plasma reactor 106. Further, to reduce the need for expensive high-voltage insulation or output stages in the primary power supply 102, the peak voltages of the power signal produce by the primary power supply may be less than 10 kV, and in some instances, below 7 kV. As noted above, the primary power supply 102 may produce an AC or DC power signal and, in some instances, may produce a pulsed power signal at a certain frequency. By adjusting certain parameters of the primary power supply 102 circuit, like a pulse width or pulsing frequency, adjustment to the average power produced by the power supply 102 may occur to alter the amount of power received at the plasma reactor 103 and to compensate for variations in input power.

When powering from an intermittent source, it is possible that less than full power may be available from the source. For example, during cloudy days, a solar array may produce power, but the power may be less than what is available on a sunny day. Similar situations may be present with wind powered turbines when the wind is blowing sub-optimally. However, the power supplies and methods described herein may be utilized in such low-power circumstances. Regardless, when sufficient power is available from a power source, whether an intermittent-power source 100, the grid or otherwise, a plasma in the plasma reactor 106 may be initiated through a trigger power supply 108 in electrical communication between the primary power supply 102 and the plasma reactor 106. In general, the amount of voltage needed to initiate a plasma is greater than the voltage needed to sustain a plasma. The trigger power supply 108 may provide the high-voltage signal necessary for such plasma initiation while the primary power supply is used to maintain a plasma. In one implementation, the trigger power supply 108 may be configured to be generally low power, providing less than 5% of the total power consumed by the plasma reactor 106, but producing relatively high-voltage pulses of up to 15 kV and, in some cases, 50 kV to ignite the plasma. For example and in some implementations, a high voltage trigger provided by the trigger power supply 108 may be based on a signal that modulates the frequency of the primary power supply 102 signal to resonate with the inductive and capacitive components in the high voltage circuitry (or the primary power supply 102), causing a much higher secondary voltage to be generated. In particular, the controller 112 may receive the signal provided by the primary power supply 102 or some measurement of the power signal from the primary power supply. The controller 112 may in turn control the trigger circuit 108 to generate a trigger power signal that resonates with the inductive and/or capacitive components of the primary power supply 102. This secondary voltage from the trigger power supply 108 can be several times the primary power voltage and may be sufficient to initiate the plasma arc. Once the arc is triggered, the frequency of the power supply signal may be brought back to the nominal operating frequency that is supported by the primary power supply 102. When placed in series as shown in the circuit 110 of FIG. 1, the need of diodes or similar protections for primary power supply 102 may be obviated.

Both the primary power supply 102 and the trigger power supply 108 may be controlled by controller 112. The controller 112 may be any type of computing device, such as a central processor, application-specific integrated circuit (ASIC), or any other integrated circuit or controller device. Control of the primary power supply 102 and the trigger power supply 108 is descried in more detail below. The controller 112 may utilize information received from one or more sensors connected to or otherwise associated with the circuit 110. For example, a voltage sensor and/or a current sensor may provide power measurement or information 114 of the power signal provided to the plasma reactor 106 from the primary power supply 102 and/or the trigger power supply 108. The controller 112 may generate one or more control signals for the primary power supply 102 and/or the trigger power supply 108 based on the measurements 114 obtained from the voltage sensor and/or the current sensor. The controller 112 may also receive one or more inputs through a user interface to further control the operation of the primary power supply 102 and/or the trigger power supply 108 to generate a plasma-arc in the reactor 106 in response to the received inputs. The control of the power supply circuit 110 is discussed in more detail below.

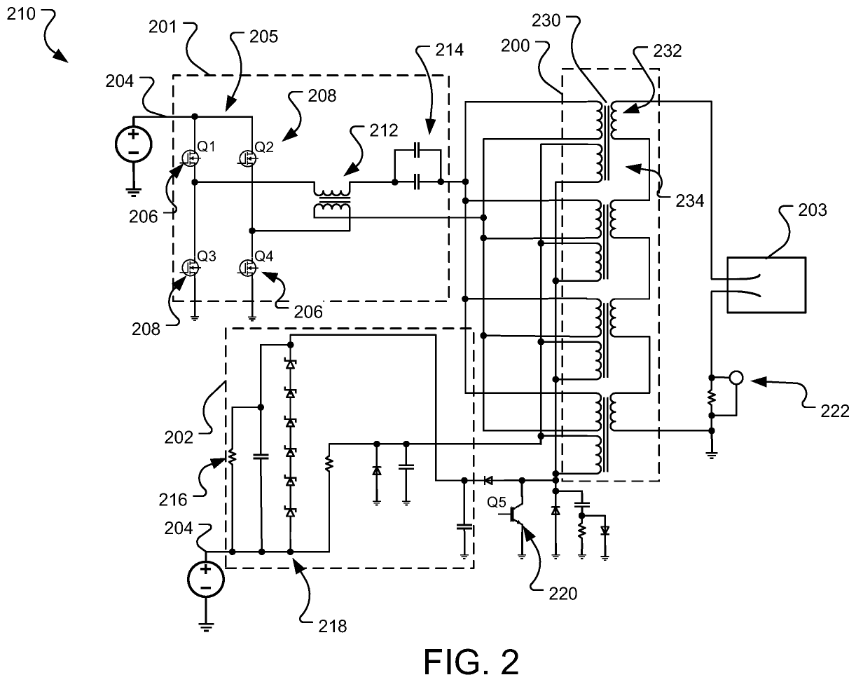

As mentioned above, the power supply circuit 110 may provide an AC power signal to the plasma reactor 106. FIG. 2 is a circuit diagram of one such plasma-arc power supply for producing a high-voltage AC output, utilizing a trigger circuit, for powering a plasma reactor. The circuit 210 may include several portions corresponding to the power supply circuit 110 of FIG. 1. For example, the AC power supply circuit 210 may include a primary power supply portion 201, a trigger circuit 202, and a plasma reactor 203. In addition, a controller (shown in FIG. 1) may provide one or more control signals to components of the primary power supply 201, the trigger circuit 202, and/or other portions of the power supply circuit 210 to control operation of the portions and provide a controlled power signal to the plasma reactor 203. The primary power supply 201 receives power from a power source 204, as described above. Although illustrated in the circuit 210 as a DC power source, which may be from a solar array, the power source 204 may be any type of power source (such as solar, wind, grid, etc.) and may provide any voltage to the primary power supply 201. Generally, speaking, the primary power supply 201 may include components to convert the DC power source 204 into an AC power signal that is provided to a transformer series 200. The transformer series 200 may produce AC power from the primary power supply 201 and provide a power signal capable of maintaining a plasma in the plasma reactor 203.

In the particular implementation illustrated in FIG. 2, the primary power supply 201 may include a bridge circuit 205 connected to the input power signal 204. In one particular implementation, the bridge circuit may include phased-offset half-bridge circuits 206, 208 connected to and controlling the input of the power source 204 to an inductor device 212. However, other bridge circuits 205 may also be included in the power supply circuit 210, including an H-bridge circuit or other bridge configurations. The half-bridge circuits may each include a pair of transistors 206, 208 or other switching elements controllable by the power supply controller 112. In particular, the controller 112 may transmit a first control signal to a first transistor pair (transistor Q1 and transistor Q4) of the bridge circuit. When transistor Q1 and transistor Q4 are closed, current from the power source 204 may flow through transistor Q1 and through inductor 212 in a first direction. Similarly, the controller 112 may transmit a second control signal to a second transistor pair (transistor Q2 and transistor Q3) of the bridge circuit. When transistor Q2 and transistor Q3 are closed, current from the power source 204 may flow through transistor Q2 and through inductor 212 in a second direction. Alternating control of the transistor pairs of the bridge circuit may generate the AC signal through inductor 212 by controlling the direction of current flow through the inductor.

The first control signal and the second control signal may, in one implementation, comprise two pulse trains that are phase offset. The amount of phase offset of the pulse-train control signals may correlate to the amount of power provided to the transformer series 200 from the primary power supply 201. For example, two pulse-train control signals 100% out of phase may result in the highest power delivery to the inductor 212, while two pulse train control signals 100% in phase may result in no power delivery to the inductor. Variations in the phase of the two control signals may therefore be utilized by the controller 112 to control the magnitude of the power signal generated by the primary power supply 201. In some instances, control of the phase of the bridge circuits 206, 208 may be associated with inputs received from a user of the power supply circuit 210, such as through an interface with the controller 112 or a physical control device to adjust the frequency of one or both of the pulse train control signals.

The primary power supply circuit 201 may also include one or more capacitors 214 to block DC current from reaching the inductor 212, which could cause saturation. In one particular implementation, the primary power supply circuit 201 may include a pair of capacitors 214 connected in parallel to each other and collectively connected in series between the inductor and the transformer series 200. The capacitor pair 214, in conjunction with the inductor 212, may convert the DC power source 204 signal into an AC power signal for transmission to the transformer series 200. For example, an output of the capacitor pair 214 may be provided as a first input to each of a group of transformers 200, the output of each of which is connected in series. The series of transformers 200 may increase the power signal from the primary power supply 201 to a level capable of sustaining a plasma in the plasma reactor 203. The series of transformers 200 may also match the impedance of the power supply to the load of the plasma reactor 203. In one particular implementation, each transformer of the transformer series 200 may include an approximate 3× winding ratio, although other winding ratios may be used depending on the needs of the plasma chamber, the power available from the supply and other factors. Further, one particular implementation includes four transformers connected in series, although the transformer series 200 may include any number of transformers. The transformer series 200 may include multiple transformers connected as illustrated, which may reduce the overall cost of the components of the power supply circuit 210 as transformers with large voltage increases may require large magnetic cores and be relatively more expensive.

The transformer series 200 may, in one example, provide a 5 kV RMS voltage and provide >95% of the energy needed by plasma reactor 203. Further, the alternating current of the power signal provided by the primary power supply 201 may be limited by the inductance 212 of the primary power supply circuit such that a need for high-voltage capacitors or resistors is eliminated, significantly simplifying the design and increasing the reliability of the circuit 210. In addition, the inductor 212 may act as a ballast to the circuit 210 upon the short-circuit condition that may occur after plasma ignition, preventing damage to the circuit components and/or power source 204. In some implementations, the primary power supply circuit 201 may operate at a frequency between 1000 Hertz (Hz) and 1 MHz, and more preferably between 5,000 and 50,000 Hz. In general, frequencies between 10,000 to 20,000 Hz may be chosen to provide a low cost and efficient operation of the circuit. In some instances, the bridge circuits 206, 208 may be configured to achieve 10 kHz switching frequencies while minimizing switching losses, such as through control by the circuit controller 112. The primary power supply circuit 201 may also, in some instances, include pulse-by-pulse current limiting techniques to provide control of high current pulses.

Although the primary power supply 201 may provide over 95% of the power to the plasma reactor 203, a trigger circuit 202 is included with and integrated with the transformer series 200 to initiate an arc in the plasma reactor 203 with sufficient power to initiate a plasma. For example, in some instances the power source 204 may not provide sufficient voltage to ignite the plasma-arc and additional voltage may be needed to ignite the arc. In such circumstances, the trigger circuit 202 may provide an ignition pulse power signal to ramp up the power provided to the plasma reactor 203 with sufficient voltage to ignite the arc. As explained in more detail below, the power to the plasma reactor 203 may then be brought back down to the power signal provided by the primary power supply 201 upon ignition and the arc may be maintained, for some period of time, by the primary power supply. This process of utilizing the trigger power supply circuit 202 to ignite the arc which is then maintained by the primary power supply circuit 201 may be repeated as needed based on the input power signal provided by the power source 204. In the example circuit 210 of FIG. 2, the trigger power supply 202 is configured to provide a current pulse to windings on series transformers 200 which, when activated, will provide high-voltages up to 50 kV, sufficient to drive an arc with sufficient power to initiate a plasma within the plasma reactor 203. As such, the transformers 200 may include a high-voltage insulation. However, the use of the trigger circuit 202 connected to the transformer series 200 may obviate the need for blocking diodes between the primary power supply 210 and the trigger power supply 202.

In some instances, the transformers of the transformer stack 200 may include one or more multi-core or multi-winding transformers. In such a circumstance, the trigger-power supply 202 or circuit may connect between the power source 204 and an additional winding on the primary side of each of the transformers of the transformer series 200. In one implementation, the additional winding of the transformers 200 may have a 27-1 winding ratio, although other winding ratios are contemplated. Through a control signal provided to trigger circuit control switch 220 (illustrated as transistor Q5, although any switching device may be included), power may be provided to the additional winding of the transformers 200 to energize the additional winding. Providing power to the additional windings of the transformers 200 may increase the voltage applied to the plasma reactor 203 to initiate an arc between the electrodes in the plasma reactor 203. For example, transformer 230 includes a first pair of windings 232 on the primary side of the transformer that amplifies an input voltage based on the winding ratio of the first pair of windings. Additional windings 234 on the primary side of the transformer 230 may be electrically connected to the trigger circuit 202 such that, when energized by the trigger circuit, the additional power to the input of the transformer increases the output voltage from the transformer that is provided to the plasma reactor 203. This “trigger winding” may be wound such that it couples more strongly to the secondary side of the transformer 230 than to the primary side in order to prevent current feedback into the inverter switching circuit. In this manner, the ignition power pulse provided by the trigger power supply circuit 202 is added to the primary power signal from the primary power supply 201, creating a boost in the provided power to the plasma reactor 203 to cause ignition of the arc. In one implementation, the trigger circuit 202 may include a resistor and capacitor 216 connected in parallel with a Zener diode ladder 218. The diode ladder 218 may protect the trigger circuit 202 from any large inductive flyback voltage from the operation of the plasma reactor 203. Additional resistors and capacitors may also be included in the trigger circuit 202.

In another implementation, the power output signal from the primary power supply circuit 201 may be provided to a first transformer or first group of transformers. The power output signal from the trigger power supply circuit 202 may alternatively be provided to a second transformer or second group of transformers that may or may not include the first transformer or first group. Thus, each power supply circuit 201, 202 may be connected to separate transformers, connected in a stack 200 as shown in FIG. 2 or separately. In general, the output signals from the power supply circuits 201, 202 may be provide to one or more transformers in any configuration.

In one implementation, the control signal to transistor Q5 220 and the transistors Q1-Q4 of the bridge circuits 206, 208 may be synchronized by the controller 112 of the circuit. In particular, the trigger circuit 202 may be controlled to provide the additional current to the transformer series 200 for the arc. Upon detection of the plasma-arc (e.g., through current sensor 222 or current transformer in electrical communication with plasma reactor 203), the trigger circuit 202 may be turned off and the primary power supply 201 may be controlled to provide the current to maintain the arc and sustain the plasma during a gliding arc phase of the plasma generation. In this manner, the control signals to control the trigger circuit 202 to initiate a plasma at the reactor 203, followed by one or more control signals to the primary power supply 201 to maintain the plasma during the gliding arc phase of the plasma. Other sensor inputs in addition to or in place of current sensor 222 may aid the controller 112 in controlling the operation of the trigger circuit 202 and the primary power supply 201 to generate an efficient plasma-arc of the plasma reactor 203 using a generated AC power signal.

Although described herein as adding the primary power signal from the primary power supply circuit 201 to the ignition pulse being added to generate the power signal to ignite the arc, the power supply circuits may be controlled in other techniques to control the plasma-arc. For example, the primary power supply circuit 201 and the trigger supply circuit 202 may operate independently to provide power to the plasma reactor 203 such that one or both of the supply circuits may provide a power signal at the same time. Further, the power signals provided by the power supply circuits 201, 202 may be unsynchronized or synchronized to work in coordination. For example, the power supply circuits 201, 202 may be controlled to provide a first power supply signal from a first power supply circuit followed by a second power supply signal from the other power supply circuit. In general, the power signals from the circuits 201, 202 may be provided in any number of techniques or sequences.

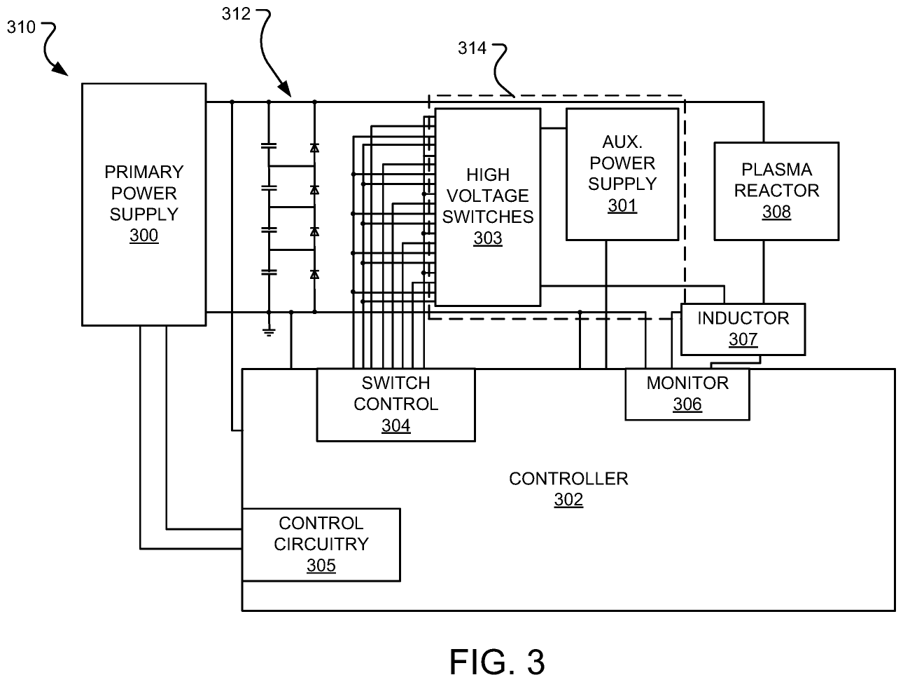

In some instances, the plasma reactor may be powered through a DC power signal. FIG. 3 is a block diagram of a plasma-arc power supply using a high-voltage direct-current (DC) output and a trigger circuit configured for integration with an intermittent power source. The power supply circuit 310 of FIG. 3 may include components similar to the power supply circuit discussed above with reference to FIG. 2. For example, the power supply circuit 310 may include a primary power supply 300 to provide a majority of the power to the plasma reactor 308. The power supply circuit 310 may also include a trigger power supply 314 (block 303 and block 301) to generate a higher voltage power signal to initiate the plasma in the reactor 308. Through control of the primary power supply 300 and the trigger power supply (e.g., from signals provided by controller 302), a plasma-arc may be generated at plasma reactor 308 for use in many applications, including nitrogen fixation plasma systems.

In the example illustrated in FIG. 3, the primary power supply 300 may include a high-voltage DC power supply. Such power supplies may be an off-the-shelf power supply, also known as capacitor-charging power supplies, configured to provide up to 5 kV of DC power or more. The average power output of primary power supply 300 may be adjustable by control circuitry 305 located on controller 302. The DC power signal provided to plasma reactor 308 may be monitored by controller 302 through one or more sensors, including monitoring section 306 of the controller.

High-voltage DC power supplies 300 of this type may be particularly sensitive to high negative voltages, such as a flyback voltage from the operation of the plasma reactor 308 when the plasma-arc is struck. To prevent damaging the primary power supply 300, protector circuit 312 may be connected in parallel to the primary power supply 300 to prevent a large negative voltage spike at the supply. In one example, the protection circuit 312 may include a capacitor stack electrically connected to a diode stack. The capacitors and/or diodes of the respective stacks may be high power components to prevent a large negative voltage at the primary power supply 300.

The trigger power supply portion of the power supply circuit 310 may include high-voltage switch 303, auxiliary power supply 301, and tapped inductor 307. In some instances, such as the exampled illustrated in FIG. 3, the high-voltage switch 303 may include several switches each controlled by a switching control section 304 of the controller 302. Auxiliary power supply 301 may be controlled by controller 302 to provide current for the trigger pulse to the high-voltage switch 303, although in other implementations the trigger power may alternatively come from the input to the primary power supply 300 or from the primary power supply itself. The high-voltage switch 303 provides a current to tapped inductor 307, which is configured to provide a high-voltage negative pulse to the plasma reactor 308. In one example, the negative pulse from the tapped inductor 307 may be a 50 kV signal. As above, this high negative pulse may initiate a spark of the plasma reactor 308 to kickstart the plasma process, at which point the controller 302 may control the high-voltage switch 303 or switches to remove the high-voltage signal from the tapped inductor 307 such that the plasma reactor 308 may be powered by the primary power supply 300. Monitoring section 306 may monitor the current and voltage of the plasma reactor 308 and tapped inductor 307 to allow for the timing of trigger pulses with arc extinction events. In this manner, the controller 302 may correspond the control of the primary power supply 300 and the trigger circuit (such as tapped inductor 307) based on measurements associated with the circuit 310, and in particular, the performance of the plasma reactor 308.

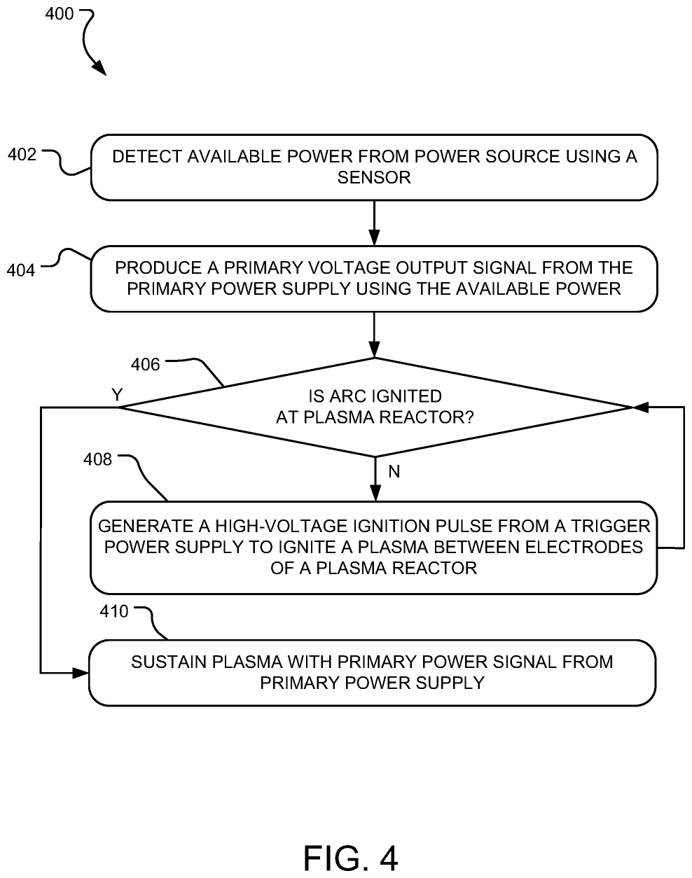

FIG. 4 is a flowchart of a method 400 for controlling a plasma-arc power supply, which includes a trigger circuit, for integration with an intermittent power source. In one implementation, the operations of the method 400 may be executed or otherwise performed by controller 112 of the power supply circuit 110 of FIG. 1. In general, however, any of the components discussed herein or any other type of computing device may execute the operations of method 400. The controller 112 may execute method 400 to utilize a trigger power supply 108 to initiate plasma generation of the plasma reactor 106 and to maintain the plasma through primary power supply 102. Both the AC power circuit 210 of FIG. 2 and/or the DC power circuit 310 of FIG. 3 may be controlled through the operations described herein to generate the plasma of the plasma reactor 103.

Beginning in operation 402, an available power from a power source 100 may be measured, which includes detecting or calculating available power. For example, voltmeter 104 of the circuit 110 of FIG. 1 may measure an input voltage of a power source 100 and provide the measurement to the controller 112. In other examples, a current meter may measure the current provided by the available power source 100 and/or a combination of voltage and current may be measured. In still further examples, an irradiance associated with a solar panel or an array of solar panels may be measured and provided to the controller 112. An available power from the solar panel array may be determined from the provided irradiance, in this example. In general, any number of measurements or conditions associated with the power supply circuit 110 may be measured and provided to the controller 112 for use in controlling the primary power supply 102 and/or the trigger power supply 108 of the circuit.

In operation 404, the controller 112 may control the primary power supply 102 to generate a primary voltage output signal based on the available power from the power source 100. For example and using the circuit 210 of FIG. 2, the controller 112 may generate and/or provide one or more control signals to the bridge circuits 206, 208 of the primary power supply 201 to generate a voltage output signal to the transformer series 200. In the example of the power supply circuit 310 of FIG. 3, the controller 302 may generate and/or provide one or more control signals to DC power source 300 to provide a voltage power signal to the plasma reactor 308. This power signal may be based on the available power from the power source 100 such that less power provided by the power source may result in a corresponding smaller voltage output signal from the primary-power supply 102. As explained in more detail below, the control of the primary power supply 102 may be based on the measured power or another aspect of the power source 100.

In operation 406, a measurement of a performance of a circuit 210 may be obtained and analyzed by the controller 112 to determine if an arc is ignited. For example, the controller 112 may receive a current measurement from current sensor 222 in communication with the plasma reactor 106. The current sensor 222 may detect a current at an electrode of the plasma reactor 103 such that an analysis of the measurement may determine if a plasma is ignited between the electrodes (such as through a detected short or near short condition across the electrodes) or if the plasma is not ignited between the electrodes (such as through a detected open or near open condition across the electrodes). In another implementation, a power output of the plasma reactor 203 may be measured or a voltage across the reactor may be measured. Regardless, the controller 112 may determine, through an analysis of the received measurement if an arc is ignited and present between the electrodes of the plasma reactor 106.

In operation 408, the controller 112 may control the trigger power supply 108 to generate a high-voltage ignition pulse between electrodes of the plasma reactor to ignite a plasma. For example, the controller 112 may close transistor Q5 220 of the circuit 210 of FIG. 2 to generate a pulse of power to the transformer series 200, which generates an ignition power pulse. Similarly, the controller 112 may generate a control signal or otherwise control high-voltage switch 303 and/or tapped inductor 307 of the power supply circuit 310 of FIG. 3 to generate the high-voltage ignition pulse. In some instances, control of the generation of the ignition pulse may be based on a measurement of a condition of the power supply circuit. For example, controlling the trigger supply to generate the ignition pulse may be based on a volt measurement 114 from a voltmeter and/or a current measurement from a current meter.

As shown in the example circuit 210 of FIG. 2, control of the trigger power supply 202 (and more particularly, switch 220) causes power from the trigger power supply to energize the additional windings on the primary side of the transformers of the transformer stack 200. For example, transformer 230 includes a first pair of windings 232 that amplifies an input voltage based on the winding ratio of the first pair of windings. A second pair of windings 234 is electrically connected to the trigger circuit 202 such that, when energized by the trigger circuit, the additional power to the input of the transformer increases the output voltage from the transformer that is provided to the plasma reactor 203. In this manner, the ignition power pulse provided by the trigger power supply circuit 202 is added to the primary power signal from the primary power supply 201, creating a bump in the provided power to the plasma reactor 203 to cause ignition of the arc. In the example circuit 310 of FIG. 3, the trigger power supply 314 controls the tapped inductor 307 to add the ignition pulse signal to the primary power signal from the primary power supply 300.

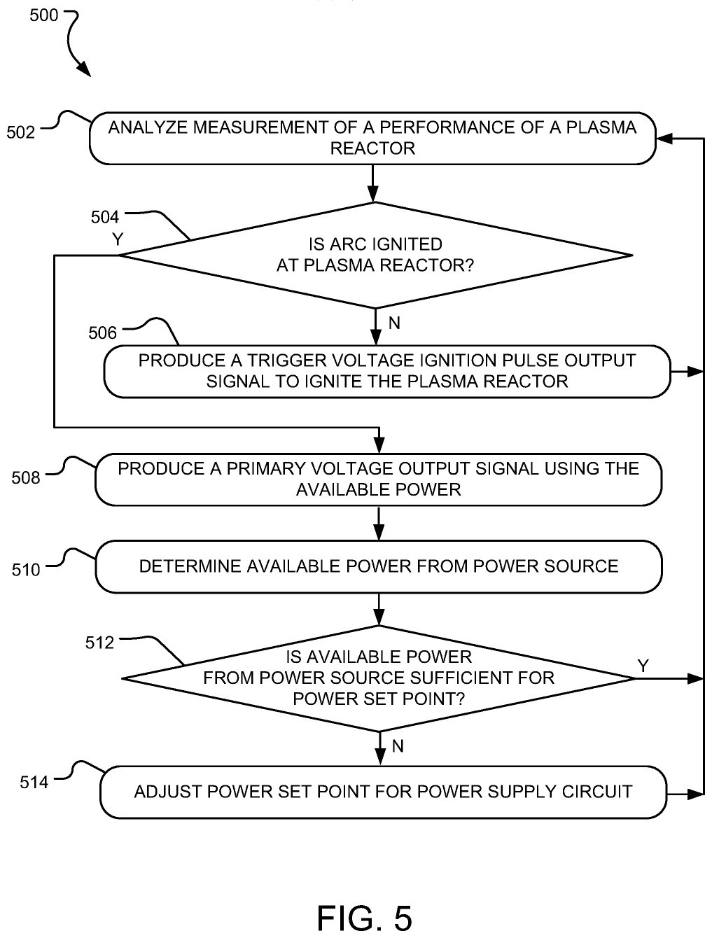

Following the ignition of the plasma from the ignition pulse of the trigger power supply 108, the controller 112 may return to operation 406 to determine if the arc is ignited from the ignition pulse. If the arc is detected as ignited, the controller 112 control the primary power supply 102 to sustain the plasma from the primary power supply in operation 410. In particular, the controller 112 may generate and/or provide control signals to the primary power supply 102 to produce a power signal to maintain the plasma for a period of time. In one implementation, the period of time for which the plasma may be maintained includes a time for the plasma to glide along the electrodes of the plasma reactor 106. Control of the primary power supply 102 to maintain the plasma is described in more detail below with reference to FIG. 5.

As mentioned above, the power supply circuits described herein may convert relatively lower power available from a low power source or intermittent power supply, such as a solar power source, a wind power source, or an intermittent power grid, into a high-voltage power source capable of producing sufficient power to ignite a plasma between electrodes of a plasma generating system. When there is insufficient power, conventional plasma power supplies are typically and simply shutdown. However, even during circumstances in which the power source provides a relatively low power signal, the power supply circuits described herein may continue to operate the plasma reactor thereby generating fertilizer if even at a lesser rate than when there is higher power available. FIG. 5 is a flowchart of a method 500 for adjusting a power setpoint of a plasma-arc power supply based on an available input power from a power source. Similar to above, the operations of the method 500 may be executed or performed by the controller 112 of the power supply circuit 110 or any other computing device associated with the power supply circuit. Further, the method 500 may be executed to control aspects of the AC power supply circuit 210 of FIG. 2 and/or the DC power supply circuit 310 of FIG. 3.

Operations 502-508 of the method 500 may be similar to those described above with reference to the method 400 of FIG. 4 for igniting the plasma-arc. For example, a measurement of a performance of a plasma reactor 103 may be obtained and analyzed in operation 502. In one example, the controller 112 may receive a current measurement from current sensor 222 in communication with the plasma reactor 103 to detect a current at an electrode of the plasma reactor 103 such that an analysis of the measurement may determine if a plasma is ignited between the electrodes (such as through a detected short or near short condition across the electrodes) or if the plasma is not ignited between the electrodes (such as through a detected open or near open condition across the electrodes). In another implementation, a power output of the plasma reactor 203 may be measured or a voltage across the reactor may be measured. Regardless, the controller 112 may determine, through an analysis of the received measurement and at operation 504, if an arc is ignited and present between the electrodes of the plasma reactor 103.

If the controller 112 determines that the plasma is not ignited, a high-voltage-ignition pulse may be generated by the trigger power supply 108 to ignite the plasma at operation 506. As described above, the controller 112 may generate one or more control signals to cause the trigger-power supply 108 to generate the ignition pulse. The controller 112 may further, after causing the trigger-power supply 108 to generate the high-voltage ignition pulse, may return to operation 502 to determine if the ignition pulse caused plasma ignition and attempt to ignite the plasma again if there is not a plasma. In some instances, a frequency control may limit the frequency at which the controller 112 causes the ignition pulse to be generated. In one particular implementation, generation of the ignition pulse may be limited to 100 Hz, although the controller 112 may be limited to any frequency of ignition pulse generation.

Upon detection of a generated plasma, the controller 112 may control the primary power supply 102 to produce a primary voltage output signal to maintain the plasma using the available power source 100 at operation 508. For example, the controller 112 may generate control signals to the bridge circuits 206, 208 of the power supply circuit 210 to generate an AC power signal for the plasma reactor 203. Further, as described above, a phase difference between the two pulse train control signals to the transistors of the bridge circuits 206, 208 may control a magnitude of the AC power signal generated by the primary power supply 201. In some instances, an input power source 100 setpoint may be determined by the controller 112 based on an available power from the power source. In general, when the available power from the power source 100 is lower than currently expected or lower (e.g., when a day transitions for sunny to cloudy, or the sun lowers on the horizon), the operational setpoint for the power supply circuit 110 may be correspondingly lowered. The controller 112, in turn, may control the primary power supply 102 and/or the trigger power supply 108 in response to the setpoint

Periodically, the controller 112 may adjust the setpoint of the available power from the power source 100 in response to a detected change in the available power. For example, the controller 112 may determine, in operation 510, an available power from the power source 100 through a measurement of an input voltage received from voltmeter 104. In other examples, a current meter may measure the current provided by the available power source 100 and/or a combination of voltage and current may be measured. In still further examples, an irradiance associated with a solar panel or an array of solar panels may be measured and provided to the controller 112. Changes in available power, particularly from a solar array, may change throughout the day based on the position of the sun relative to the array and the degree of cloud cover, among other things. Based on the measured or determined available power from the power source 100, the controller 112 may determine, in operation 512, if the available power is sufficient to meet a currently determined setpoint for operating the primary power supply 102 and/or the trigger power supply 108. If the available power from the power source 100 is sufficient to meet the setpoint to generate a power signal to ignite the plasma based on the settings of the controller, the controller may return to operation 502 to start the method 500 of FIG. 5 again. However, if the controller 112 determines that the available power is insufficient to ignite the plasma or is an inefficient consumption of the available power, the controller may adjust the power setpoint for the power supply circuit 110 in operation 514. The controller 112 may adjust the setpoint lower in cases in which the measured input power indicates that the power supply circuit 110 consumes an inefficient amount of the input power. Alternatively, the controller 112 may adjust the power setpoint higher in cases in which the measured input power indicates that the power supply circuit 110 may be insufficient to ignite the plasma at the current control configuration of the controller. Regardless of the adjustment to the power setpoint, the controller 112 may return to operation 502 to repeat the method 500 of FIG. 5. In this manner, the power supply circuit 110 may respond to an intermittent power source, such as renewable energy power source or an intermittent grid connection.

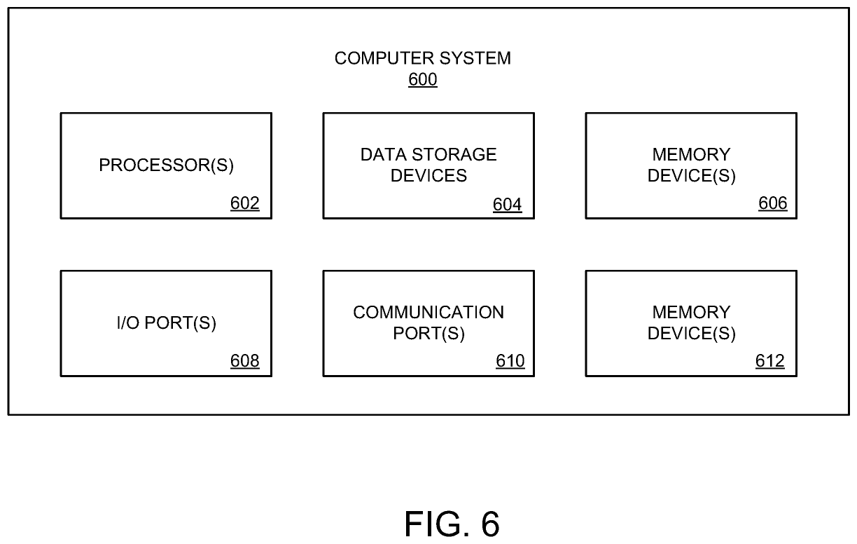

Referring to FIG. 6, a detailed description of an example computing system 600 having one or more computing units that may implement various systems and methods discussed herein is provided. The computing system 600 may be or be a part of a controller (e.g., controller 302) may be in operable communication with various implementation discussed herein, may run various operations related to the method discussed herein, may run offline to process various data for characterizing a battery, and may be part of overall systems discussed herein. The computing system 600 may process various signals discussed herein and/or may provide various signals discussed herein. It will be appreciated that specific implementations of these devices may be of differing possible specific computing architectures, not all of which are specifically discussed herein but will be understood by those of ordinary skill in the art. It will further be appreciated that the computer system may be considered and/or include an ASIC, FPGA, microcontroller, or other computing arrangement. In such various possible implementations, more or fewer components discussed below may be included, interconnections and other changes made, as will be understood by those of ordinary skill in the art. In various implementations, the system may further include an analog to digital converter, pulse width modulation, such as to drive the bridge circuit 205, and comparator modules.

The computer system 600 may be a computing system that is capable of executing a computer program product to execute a computer process. Data and program files may be input to the computer system 600, which reads the files and executes the programs therein. Some of the elements of the computer system 600 are shown in FIG. 6, including one or more hardware processors 602, one or more data storage devices 604, one or more memory devices 606, and/or one or more ports 608-612. Additionally, other elements that will be recognized by those skilled in the art may be included in the computing system 600 but are not explicitly depicted in FIG. 6 or discussed further herein. Various elements of the computer system 600 may communicate with one another by way of one or more communication buses, point-to-point communication paths, or other communication means not explicitly depicted in FIG. 6.

The processor 602 may include, for example, a central processing unit (CPU), a microprocessor, a microcontroller, a digital signal processor (DSP), and/or one or more internal levels of cache. There may be one or more processors 602, such that the processor 602 comprises a single central-processing unit, or a plurality of processing units capable of executing instructions and performing operations in parallel with each other, commonly referred to as a parallel processing environment.

The presently described technology in various possible combinations may be implemented, at least in part, in software stored on the data stored device(s) 604, stored on the memory device(s) 606, and/or communicated via one or more of the ports 608-612, thereby transforming the computer system 600 in FIG. 6 to a special purpose machine for implementing the operations described herein.

The one or more data storage devices 604 may include any non-volatile data storage device capable of storing data generated or employed within the computing system 600, such as computer executable instructions for performing a computer process, which may include instructions of both application programs and an operating system (OS) that manages the various components of the computing system 600. The data storage devices 604 may include, without limitation, magnetic disk drives, optical disk drives, solid state drives (SSDs), flash drives, and the like. The data storage devices 604 may include removable data storage media, non-removable data storage media, and/or external storage devices made available via a wired or wireless network architecture with such computer program products, including one or more database management products, web server products, application server products, and/or other additional software components. Examples of removable data storage media include Compact Disc Read-Only Memory (CD-ROM), Digital Versatile Disc Read-Only Memory (DVD-ROM), magneto-optical disks, flash drives, and the like. Examples of non-removable data storage media include internal magnetic hard disks, SSDs, and the like. The one or more memory devices 606 may include volatile memory (e.g., dynamic random access memory (DRAM), static random access memory (SRAM), etc.) and/or non-volatile memory (e.g., read-only memory (ROM), flash memory, etc.).

Computer program products containing mechanisms to effectuate the systems and methods in accordance with the presently described technology may reside in the data storage devices 604 and/or the memory devices 606, which may be referred to as machine-readable media. It will be appreciated that machine-readable media may include any tangible non-transitory medium that is capable of storing or encoding instructions to perform any one or more of the operations of the present disclosure for execution by a machine or that is capable of storing or encoding data structures and/or modules utilized by or associated with such instructions. Machine-readable media may include a single medium or multiple media (e.g., a centralized or distributed database, and/or associated caches and servers) that store the one or more executable instructions or data structures.

In some implementations, the computer system 600 includes one or more ports, such as an input/output (I/O) port 608, a communication port 610, and a sub-systems port 612, for communicating with other computing, network, or vehicle devices. It will be appreciated that the ports 608-612 may be combined or separate and that more or fewer ports may be included in the computer system 600. The I/O port 608 may be connected to an I/O device, or other device, by which information is input to or output from the computing system 600. Such I/O devices may include, without limitation, one or more input devices, output devices, and/or environment transducer devices.

In one implementation, the input devices convert a human-generated signal, such as, human voice, physical movement, physical touch or pressure, and/or the like, into electrical signals as input data into the computing system 600 via the I/O port 608. In some examples, such inputs may be distinct from the various system and method discussed with regard to the preceding figures. Similarly, the output devices may convert electrical signals received from computing system 600 via the I/O port 608 into signals that may be sensed or used by the various methods and system discussed herein. The input device may be an alphanumeric input device, including alphanumeric and other keys for communicating information and/or command selections to the processor 602 via the I/O port 608. The input device may be another type of user input device including, but not limited to: direction and selection control devices, such as a mouse, a trackball, cursor direction keys, a joystick, and/or a wheel; one or more sensors, such as a camera, a microphone, a positional sensor, an orientation sensor, a gravitational sensor, an inertial sensor, and/or an accelerometer; and/or a touch-sensitive display screen (“touchscreen”). The output devices may include, without limitation, a display, a touchscreen, a speaker, a tactile and/or haptic output device, and/or the like. In some implementations, the input device and the output device may be the same device, for example, in the case of a touchscreen.

The environment transducer devices convert one form of energy or signal into another for input into or output from the computing system 600 via the I/O port 608. For example, an electrical signal generated within the computing system 600 may be converted to another type of signal, and/or vice-versa. In one implementation, the environment transducer devices sense characteristics of the plasma chamber, input or output to and from the chamber, light and other environmental conditions local or remote, the power available from the power source or other attributes of the power source among other things.

In one implementation, a communication port 610 may be connected to a network by way of which the computer system 600 may receive network data useful in executing the methods and systems set out herein as well as transmitting information and network configuration changes determined thereby. For example, power management protocols may be updated, power measurement or calculation data shared with external system or the local system, and the like. The communication port 610 connects the computer system 600 to one or more communication interface devices configured to transmit and/or receive information between the computing system 600 and other devices by way of one or more wired or wireless communication networks or connections. Examples of such networks or connections include, without limitation, Universal Serial Bus (USB), Ethernet, Wi-Fi, Bluetooth®, Near Field Communication (NFC), Long-Term Evolution (LTE), and so on. One or more such communication interface devices may be utilized via the communication port 610 to communicate with one or more other machines, either directly over a point-to-point communication path, over a wide area network (WAN) (e.g., the Internet), over a local area network (LAN), over a cellular (e.g., third generation (3G), fourth generation (4G), fifth generation (5G)) network, or over another communication means.

The computer system 600 may include a sub-systems port 612 for communicating with one or more systems related to a device being charged according to the methods and system described herein to control an operation of the same and/or exchange information between the computer system 600 and one or more sub-systems of the device.

The system set forth in FIG. 6 is but one possible example of a computer system that may employ or be configured in accordance with aspects of the present disclosure. It will be appreciated that other non-transitory tangible computer-readable storage media storing computer-executable instructions for implementing the presently disclosed technology on a computing system may be utilized.

In the present disclosure, the methods disclosed may be implemented as sets of instructions or software readable by a device. Further, it is understood that the specific order or hierarchy of steps in the methods disclosed are instances of example approaches. Based upon design preferences, it is understood that the specific order or hierarchy of steps in the method can be rearranged while remaining within the disclosed subject matter. The accompanying method claims present elements of the various steps in a sample order, and are not necessarily meant to be limited to the specific order or hierarchy presented.

The described disclosure may be provided as a computer program product, or software, that may include a non-transitory machine-readable medium having stored thereon instructions, which may be used to program a computer system (or other electronic devices) to perform a process according to the present disclosure. A machine-readable medium includes any mechanism for storing information in a form (e.g., software, processing application) readable by a machine (e.g., a computer). The machine-readable medium may include, but is not limited to, magnetic storage medium, optical storage medium; magneto-optical storage medium, read only memory (ROM); erasable programmable memory (e.g., EPROM and EEPROM); flash memory; or other types of medium suitable for storing electronic instructions.

Embodiments of the present disclosure include various steps, which are described in this specification. The steps may be performed by hardware components or may be embodied in machine-executable instructions, which may be used to cause a general-purpose or special-purpose processor programmed with the instructions to perform the steps. Alternatively, the steps may be performed by a combination of hardware, software and/or firmware.

Various modifications and additions can be made to the exemplary embodiments discussed without departing from the scope of the present invention. For example, while the embodiments described above refer to particular features, the scope of this invention also includes embodiments having different combinations of features and embodiments that do not include all of the described features. Accordingly, the scope of the present invention is intended to embrace all such alternatives, modifications, and variations together with all equivalents thereof.

While specific implementations are discussed, it should be understood that this is done for illustration purposes only. A person skilled in the relevant art will recognize that other components and configurations may be used without parting from the spirit and scope of the disclosure. Thus, the following description and drawings are illustrative and are not to be construed as limiting. Numerous specific details are described to provide a thorough understanding of the disclosure. However, in certain instances, well-known or conventional details are not described in order to avoid obscuring the description. References to one or an embodiment in the present disclosure can be references to the same embodiment or any embodiment; and, such references mean at least one of the embodiments.

Reference to “one embodiment” or “an embodiment” means that a particular feature, structure, or characteristic described in connection with the embodiment is included in at least one embodiment of the disclosure. The appearances of the phrase “in one embodiment” in various places in the specification are not necessarily all referring to the same embodiment, nor are separate or alternative embodiments mutually exclusive of other embodiments. Moreover, various features are described which may be exhibited by some embodiments and not by others.

The terms used in this specification generally have their ordinary meanings in the art, within the context of the disclosure, and in the specific context where each term is used. Alternative language and synonyms may be used for any one or more of the terms discussed herein, and no special significance should be placed upon whether or not a term is elaborated or discussed herein. In some cases, synonyms for certain terms are provided. A recital of one or more synonyms does not exclude the use of other synonyms. The use of examples anywhere in this specification including examples of any terms discussed herein is illustrative only, and is not intended to further limit the scope and meaning of the disclosure or of any example term. Likewise, the disclosure is not limited to various embodiments given in this specification.

Without intent to limit the scope of the disclosure, examples of instruments, apparatus, methods and their related results according to the embodiments of the present disclosure are given below. Note that titles or subtitles may be used in the examples for convenience of a reader, which in no way should limit the scope of the disclosure. Unless otherwise defined, technical and scientific terms used herein have the meaning as commonly understood by one of ordinary skill in the art to which this disclosure pertains. In the case of conflict, the present document, including definitions will control.

Additional features and advantages of the disclosure will be set forth in the description which follows, and in part will be obvious from the description, or can be learned by practice of the herein disclosed principles. The features and advantages of the disclosure can be realized and obtained by means of the instruments and combinations particularly pointed out in the appended claims. These and other features of the disclosure will become more fully apparent from the following description and appended claims, or can be learned by the practice of the principles set forth herein.

We claim:

1. A power supply for a plasma reactor comprising:
a primary-power supply circuit converting an input power signal from a power source to a primary voltage power signal to maintain a plasma-arc;
a trigger-power supply circuit generating an ignition power pulse signal to ignite the plasma-arc; and
a controller in communication with the primary-power supply circuit and the trigger-power supply circuit, the controller generating one or more control signals to activate, based on a measurement associated with the plasma reactor, the trigger-power supply circuit.

2. The power supply of claim 1 wherein the controller further generates the one or more control signals based on an available power from the power source.

3. The power supply of claim 1 wherein the primary voltage power signal is added to the ignition power pulse signal to sustain the ignited plasma-arc.

4. The power supply of claim 1 wherein the primary-power supply circuit comprises:
a first half-bridge circuit comprising a first pair of switching devices;
a second half-bridge circuit comprising a second pair of switching devices electrically connected in parallel with the first pair of switching devices;
an inductor device electrically connected to an output of the first half-bridge circuit and an output of the second half-bridge circuit; and
a transformer electrically connected to an output of the inductor device.

5. The power supply of claim 4 wherein the controller further generates a first half-bridge control signal and a second half-bridge control signal out of phase with the first half-bridge control signal, the first half-bridge control signal transmitted to at least one of the first pair of switching devices and the second half-bridge control signal transmitted to at least one of the second pair of switching devices.

6. The power supply of claim 5 wherein a phase difference of the first half-bridge control signal and the second half-bridge control signal is based on a power setpoint determined by the controller.

7. The power supply of claim 4 wherein the trigger-power supply circuit is in electrical communication with the transformer to, when activated by the controller, energize an additional winding of the transformer to increase a power provided to the plasma reactor.

8. The power supply of claim 4 wherein the inductor device prevents a high negative voltage pulse from feeding back to the first half-bridge circuit and the second half-bridge circuit.

9. The power supply of claim 1 wherein the primary-power supply circuit is a direct current (DC) high-voltage power supply.

10. The power supply of claim 9, further comprising:
a protection circuit comprising a capacitor stack and a diode stack, the protection circuit preventing a high-negative-voltage pulse from the DC high-voltage power supply.

11. The power supply of claim 9 wherein the trigger-power supply circuit comprises a tapped inductor in electrical communication with the plasma reactor.

12. The power supply of claim 1 wherein the power source comprises a solar array, a wind turbine, and a power grid.

13. The power supply of claim 1 wherein the power source is an intermittent power source.

14. The power supply of claim 1 wherein the ignition power pulse signal is between 1 V and 10 kV.

15. The power supply of claim 1 wherein the ignition power pulse signal is between 1 V and 50 kV.

16. The power supply of claim 1 wherein the primary-power supply circuit provides above 95% of a total power to the plasma reactor.

17. The power supply of claim 1 wherein the ignition power pulse signal is an alternating-current-power signal or a direct-current-power signal.

18. The power supply of claim 1 wherein the one or more control signals activate the trigger-power supply circuit to generate the ignition power pulse signal comprising a frequency resonate with an inductive component or a capacitive component of the primary-power supply circuit.

19. The power supply of claim 1 wherein the trigger-power supply circuit is in electrical communication with a pair of electrodes of the plasma reactor and wherein the plasma-arc is between the electrodes to ignite a plasma within the plasma reactor and the primary-power supply circuit is in electrical communication with the pair of electrodes of the plasma reactor and wherein the plasma-arc is maintained between the electrodes to sustain the plasma after ignition, the plasma to produce a nitrogen-based chemical fertilizer.

20. A power supply for a plasma reactor comprising:
a primary-power supply circuit receiving a power signal from a power source and outputting a primary-power signal, the primary-power supply circuit comprising:
a bridge circuit in electrical communication with the power signal and controlled by phase-offset-activation signals; and
an inductor in electrical communication with an output of the bridge circuit;
a transformer electrically connected to an output of the inductor device, the transformer amplifying the primary-power signal to the plasma reactor; and
a trigger-power supply circuit converting the power signal from the power source to a high-voltage, ignition-power-pulse signal added to the primary-power signal to ignite a plasma-arc.

21. The power supply of claim 20 wherein high-voltage inductor device prevents a high-voltage flyback signal from the bridge circuit.

22. The power supply of claim 20 wherein the transformer is one of a plurality of transformers, the outputs of each of the plurality of transformers connected in a series connection to the plasma reactor.

23. The power supply of claim 20 wherein the bridge circuit, the inductor, or the transformer operate at a frequency between 1,000 Hertz and 1 Megahertz.

24. The power supply of claim 23 wherein the transformer comprises a multi-winding transformer comprising a first primary winding connected to an output of the primary-power supply circuit and a second primary winding connected to an output of the trigger-power supply circuit.

25. The power supply of claim 20 wherein the power source is an intermittent power source.

26. The power supply of claim 25 wherein the intermittent power source comprises one of a solar array and a wind turbine.

27. The power supply of claim 25 wherein the trigger-power supply circuit generates the high-voltage, ignition power pulse signal during a detected insufficient power period from the intermittent power source.

28. A method for controlling a plasma reactor, the method comprising:
generating, from a primary-power supply circuit, a primary power signal from an initial power signal received from a power source;
detecting a high-resistance condition across a plurality of electrodes of the plasma reactor;
generating, from a trigger-power supply circuit different than the primary-power supply circuit, an ignition-power-pulse signal to ignite a plasma-arc; and
controlling the primary-power supply circuit to generate a sustaining-power signal to sustain the plasma-arc.

29. A method for controlling a plasma reactor, the method comprising:
measuring, from a power source and at a power supply, an indication of available power from an intermittent power source;
setting, based on the indication of available power, a first power set point for the power supply;
determining a change in the available power from the intermittent power source; and
adjusting, based on the determined change in the available power from the intermittent power source, the power set point for the power supply, wherein adjusting the power set point provides a power signal to the plasma reactor corresponding to the available power from the intermittent power source.
